(19) United States
(12) Patent Application Publication
(10) Pub. No.: US 2025/0081390 A1
(43) Pub. Date: Mar. 6, 2025

(54) COOLING PLATE, BATTERY DISCONNECT UNIT, AND A DRIVE SYSTEM

(71) Applicant: Robert Bosch GmbH, Stuttgart (DE)

(72) Inventor: Markus Schmitt, Tamm (DE)

(21) Appl. No.: 18/824,115

(22) Filed: Sep. 4, 2024

(30) Foreign Application Priority Data
Sep. 4, 2023 (DE) 10 2023 208 509.7

(51) Int. Cl. H05K 7/20; H01M 10/613; H01M 10/6554

(52) U.S. Cl. CPC H05K 7/20254; H01M 10/613; H01M 10/6554

(57) ABSTRACT

A cooling plate for cooling a component and a power electronics unit, and for cooling a relay of a battery disconnect unit, includes a first plate and a second plate. The first plate and the second plate comprise a component portion such that the component can be arranged on the component portion of the first plate. A first flow chamber for a coolant is provided in the component portion between the first plate and the second plate. The first plate and the second plate include a relay portion such that the relay of the battery disconnect unit or a fastening element of the relay can be arranged on the relay portion. A second flow chamber for a coolant is provided in the relay portion between the first plate and the second plate and the first flow chamber and the second flow chamber are fluidically connected.

### BACKGROUND

The invention relates to a cooling plate, a battery disconnect unit, and a drive system.

According to the prior art, a battery disconnect unit (BDU) is used to switch the battery of an electric vehicle on and off, depending on the operating status. In this context, the three BDU configurations specified are usually used:
1. fuse and relay
2. pyro fuse and relay
3. fuse, pyro fuse, and relay

When using a combination of relays and a circuit using SiC-based semiconductors (AMB component) for a BDU, active cooling of these components is necessary. This is achieved by, e.g., a cooling plate, through which a coolant flows. According to the prior art, a cooling plate made of aluminum sheets in a brazing process can be used in this case. Depending on the requirements with regard to the currents being switched, and thus the power losses in the form of heat, these cooling plates can be equipped with an additional water fin (internal insert) to increase the cooling capacity.

DE 10 2020 206 338 and DE 10 2020 206 339 describe how the heat dissipation of a relay can be achieved via a thermal connection of the busbars (busbar) in the direct vicinity of the relay and/or the thermal connection of the relay itself to the battery housing (heat sink).

DE 11 2015 003 530 describes a heat exchanger composed of a pair of plates.

When cooling AMB modules together with the cooling of one or multiple relay assembly using a single cooling plate, the problem arises (depending on the available installation space) that the two regions being cooled may have a negative thermal effect on each other.

In other words, when the AMB components are cooled, the heat flow has a negative effect on the relay cooling region, and vice versa. This leads to an increase in temperature, both on the AMB modules and on the components of the relay assembly, thus having a negative effect on, e.g., component service life.

### SUMMARY

The invention proposes a cooling plate, a battery disconnect unit, and a drive system having the features of the disclosure. Features and details described in connection with the cooling plate according to the invention obviously also apply in connection with the battery disconnect unit according to the invention and/or in connection with the drive system according to the invention, and vice versa in each case, so that reference is or can always be made mutually to the individual aspects of the invention with regard to the disclosure.

A first aspect of the invention is a cooling plate for cooling at least one component, in particular a plurality of components and at least one power electronics unit, and for cooling at least one relay of a battery disconnect unit used for disconnecting a battery unit from at least one consumer of a drive system. The cooling plate comprises a first plate and a second plate, the first plate and the second plate having a component portion, whereby the at least one component can be arranged on the component portion of the first plate, and whereby a first flow chamber for a coolant is provided in the component portion between the first plate and the second plate, The first plate and the second plate further comprise a relay portion, whereby the at least one relay of the battery disconnect unit or at least one fastening element of the at least one relay of the battery disconnect unit can be arranged on the relay portion, and whereby a second flow chamber for a coolant is provided in the relay portion between the first plate and the second plate. The first flow chamber and the second flow chamber are thereby fluidically connected.

To form the cooling plate, the first plate and the second plate can be interconnected via an material bond at a connecting edge, e.g. via a soldered joint.

This cooling plate enables the power electronics unit to be geometrically and thermally decoupled by the component portion and the at least one relay by the relay portion. This minimizes the negative effects of the interaction between the two regions. At the same time, the cooling plate increases the service life of the components and thus that of the battery disconnect unit.

In order to thermally decouple the two regions and thus prevent or minimize a negative interaction of the two heat flows occurring in the component portion and the relay portion, the cooling plate is geometrically designed such that the heat input from the power electronics unit is dissipated through a first flow chamber and the heat input from the relay is dissipated through a second flow chamber of the cooling channel. This means that the coolant is actively flows under both regions during operation, thus enabling the heat flow in the first flow chamber and the second flow chamber to be dissipated directly to the coolant. As a result, a heat flow from the power electronics unit is prevented from reaching the relay or relay assembly and leading to an additional temperature increase in the relay or relay assembly. At the same time, the direct undercurrent of the power electronics unit in the first flow chamber enables a high heat flow to be dissipated over a small area.

The result is a positive effect on the service life of the components, while also preventing a heat flow from the relay assembly reaching the power electronics unit region and causing a temperature increase there. Here too, the service life of the power electronics unit can be positively influenced.

The battery unit is disconnected from the consumer via the power electronics unit (e.g., SiC Mosfet AMB) and/or via the relay. The relay is in this case part of the battery disconnect unit. The power electronics unit is also part of the battery disconnect unit. The relay is necessary to meet the requirement for galvanic isolation. The relay disconnects the positive battery terminal from the consumer. The power electronics unit disconnects the negative battery terminal from the consumer.

In the context of the invention, it can be advantageous for the second flow chamber of the relay portion to be channel-shaped.

As a result, it is easy to increase the flow velocity for flowing under the relay. At the same time, the course of the second flow chamber can be adapted to the special features of the heat dissipation of a relay. For example, this channel-shaped second flow chamber can comprise deflections that lead to a change in the direction of the flow. The course of the second flow chamber can be designed such that the relay or relay group can be cooled at least two positions, rather than just one.

Within the scope of the invention, it is conceivable that the first flow chamber comprises a coolant distribution region having a coolant inlet and a deflection region for deflecting the coolant into the second flow chamber, and that the second flow chamber comprises a coolant collection region having a coolant outlet.

The shape of the coolant distribution region, which is usually V-shaped and widens towards the flow region, ensures that the coolant entering via the coolant inlet is distributed over the entire cross-sectional area so that the base surface of the power electronics unit in the component portion is subjected to an undercurrent in order to be able to dissipate its heat. By reducing the cross-section in the coolant collection region, the speed of the coolant flow is increased so that the heated coolant can quickly exit the flow chamber.

This is a simple way of ensuring that the heat generated by the power electronics unit can be discharged quickly and effectively.

Within the scope of the invention, it can be provided that the first plate and the second plate in the relay portion have a recess for receiving the at least one relay in certain regions and at least one support region for supporting the at least one relay or the at least one fastening element of the at least one relay.

This enables a compact design of the cooling plate, so that cooling or heat dissipation can take place in the relay portion without having to accept restrictions on the installation space.

It is conceivable that the cooling plate is designed such that the relay is supported on one or more fastening elements on the cooling plate, whereby the relay is arranged in the receptacle and is cooled via the fastening element. In this case, the fastening element(s) is/are arranged such that they are then directly subjected to an undercurrent in the relay portion.

It is also conceivable that the relay portion of the cooling plate be designed to support a portion of the relay or relay assembly, with another portion being located in the recess.

The cooling plate or relay portion can thus be adapted to the installation space in general, as well as to the relay or relay assembly and its geometric shape, and/or its heat dissipation requirements.

It is also conceivable that at least sections of the second flow chamber are designed to extend around the recess.

The stability of the cooling plate can thus be ensured. At the same time, the second flow chamber can be designed to extend around the recess such that at least two regions of the relay or the fastening elements of the relay are cooled. The position of the coolant outlet can also be easily adapted to specifications relating to connection points by extending around the second flow chamber.

It is also conceivable that a flow grid is arranged between the coolant distribution region and the deflection region of the first flow chamber.

The turbulence in the flow chamber can be increased by means of the flow grille, which increases the heat transfer of the heat to the coolant. The flow grid also serves to support the internal pressure created by the coolant.

The flow grid can be connected via a material bond to the first plate and/or the second plate.

Within the scope of the invention, it is optionally possible for the first plate and/or the second plate to have a deformation to form the first flow chamber and the second flow chamber.

One of the plates can also be planar, whereby the power electronics component is arranged on the planar plate.

The deformation is easy to produce, and its dimensions, in particular the forming depth, have an influence on the flow cross-section in the undercurrent of the component and can thus determine the flow velocity.

Furthermore, it can be provided within the scope of the invention that a second thickness of the second plate is at least 1.0 times, preferably at least 1.5 times, further preferably at least 2.0 times, a first thickness of the first plate.

Different thicknesses can ensure the stability of the cooling plate with effective heat transfer from the component or relay to the coolant.

A second aspect of the invention is a battery disconnection unit used for disconnecting a battery unit from at least one consumer,
comprising a cooling plate according to a first aspect of the invention,
comprising at least one ceramic substrate,
comprising at least one component of at least the power electronics unit, whereby the at least one ceramic substrate is arranged on an outer side of the first plate at the component portion, and whereby the at least one component is arranged on the ceramic substrate, and whereby the first flow chamber is arranged below the at least one component of the power electronics unit, and
comprising at least one relay, whereby the at least one relay is arranged at the relay portion, the second flow chamber being arranged below the at least one relay or the at least one fastening element of the at least one relay.

A cold-sprayed copper layer is preferably applied to the cooling plate for the thermal and mechanical connection of the power electronics components. In a further soldering process, the underside (copper alloy) of the power electronics components is materially bonded to the copper layer on the cooling plate. As a result, a very effective thermal transfer is achieved from the component to the cooling plate, and thus into the coolant.

The width of the first flow chamber corresponds at least to the width of the power electronics component and its length corresponds at least to the length of the power electronics component, so the base surface of the power electronics component is directly subjected to an undercurrent in order to dissipate the heat.

The heat flows from the relay to the cooling plate or from the relay via its fastening elements to the cooling plate and via its structure into the second flow chamber and thus to the coolant. The regions being cooled by the relay heat dissipation are subjected to an undercurrent by way of a cooling channel.

With regard to the present invention, it is conceivable that the relay be arranged in the recess and be supported on the at least one support region via the at least one fastening element.

This is particularly space efficient. The relay is in this case cooled via the at least one fastening element.

The relay or the at least one fastening element is supported on the cooling plate, with the relay being arranged in the receptacle and being cooled via the fastening element. The fastening element or elements are then arranged to be directly subjected to an undercurrent in the relay portion.

It is also conceivable that the at least one fastening element is a busbar.

The busbar can be used to ensure the electrical connection, while simultaneously supporting the relay.

A third aspect of the invention is a drive system comprising a battery unit, a consumer, and a battery disconnect unit according to a second aspect, whereby the battery unit and the battery disconnect unit are electronically connected to each other via a battery interface of the battery disconnect unit, and whereby the consumer and the battery disconnect unit are connected to each other via a consumer interface of the battery disconnect unit.

The drive system comprises the battery disconnect unit described hereinabove and the advantages thereof. Advantages which have been described in detail with respect to the cooling plate according to the first aspect of the invention apply equally to the battery disconnect unit according to the second aspect of the invention and the drive system according to the third aspect of the invention.

Further advantages, features, and details of the invention follow from the description hereinafter, in which several exemplary embodiments of the invention are described in detail with reference to the drawings. In this context, the features mentioned in the claims and in the description can each be essential to the invention individually or in any combination. The invention is illustrated in the following drawings:

### BRIEF DESCRIPTION OF THE DRAWINGS

FIG. 1 a schematic illustration of a cooling plate according to the invention,

FIG. 2 a schematic illustration of a battery disconnect unit according to the invention,

FIG. 3 a schematic illustration of a drive system according to the invention.

### DETAILED DESCRIPTION

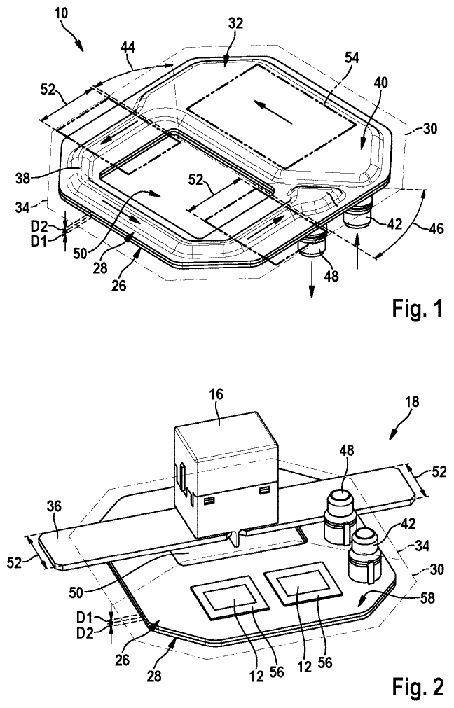

FIG. 1 shows a cooling plate 10 for cooling at least one component 12, in particular a plurality of components 12, at least one power electronics unit 14, and for cooling at least one relay 16 of a battery disconnect unit 18 for disconnecting a battery unit 20 from at least one consumer 22 of a drive system 24. The cooling plate 10 comprises a first plate 26 and a second plate 28. The first plate 26 and the second plate 28 comprise a component portion 30. The at least one component 12 can be arranged on the component portion 30 of the first plate 26.

A first flow chamber 32 for a coolant is provided in the component portion 30, between the first plate 26 and the second plate 28. The first plate 26 and the second plate 28 further comprise a relay portion 34. The at least one relay 16 of the battery disconnect unit 18 or at least one fastening element 36 of the at least one relay 16 of the battery disconnect unit 18 can be arranged on the relay portion 34.

A second flow chamber 38 for a coolant is provided in the relay portion 34, between the first plate 26 and the second plate 28. The first flow chamber 32 and the second flow chamber 38 are fluidically connected such that the coolant flows from the first flow chamber 32 into the channel-shaped second flow chamber 38 of the relay portion 34.

For the inflow of the coolant, the first flow chamber 32 comprises a coolant distribution region 40 having a coolant inlet 42 and a deflection region 44 for deflecting the coolant into the second flow chamber 38. The second flow chamber 38 comprises a coolant collection region 46 having a coolant outlet 48 for the coolant to flow out.

In order to achieve a compact design of the cooling plate 10, the first plate 26 and the second plate 28 comprise a recess 50 in the relay portion 34 for receiving the at least one relay 16 in certain regions, and at least one support region 52 for supporting the at least one relay 16 or the at least one fastening element 36 of the at least one relay 16.

At least sections of the second flow chamber 38 in this case extend around the recess 50 so that the support regions 52 are subjected to an undercurrent by the coolant in the second flow chamber 38 and thus serve to cool the relay 16.

To maximize the surface area, a flow grid 54 is arranged between the coolant distribution region 40 and the deflection region 44 of the first flow chamber. This is not illustrated herein.

To form the first and second flow chamber, the second plate 28 comprises a deformation, whereby the first plate 26 is planar.

It is also conceivable that the first plate 26 additionally or alternatively comprises the deformation.

For better heat transfer, a second thickness D2 of the second plate 28 is at least 1.5 times a first thickness D1 of the first plate 26, whereby the first thickness D1 and the second thickness D2 can also be the same.

FIG. 2 shows a battery disconnect unit 18 comprising a cooling plate 10 according to FIG. 1, comprising at least one ceramic substrate 56, comprising at least one component 12 of at least the power electronics unit 14, and comprising at least one relay 16. In this case, the at least one ceramic substrate 56 is arranged on an outer side 58 of the first plate 26 at the component portion 30, and the at least one component 12 is arranged on the ceramic substrate 56. The first flow chamber 32 is in this case arranged below the at least one component 12 of the power electronics unit 14. The at least one relay 16 is provided on the relay portion 34 such that the second flow chamber 38 is arranged below the at least one relay 16 or the at least one fastening element 36 of the at least one relay 16.

As can be seen, the relay 16 is arranged in the recess 50 and supported on the at least one support region 52 via the at least one fastening element 36. The at least one fastening element 36 is a busbar, so the electrical connection is ensured at the same time.

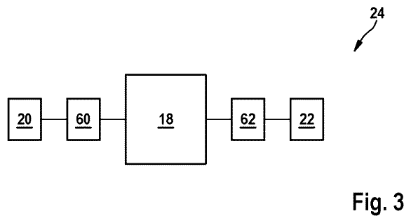

FIG. 3 shows a drive system 24 comprising a battery unit 20, a consumer 22, and a battery disconnect unit 18, as shown in FIG. 2. In the present case, the battery unit 20 and the battery disconnect unit 18 are electronically connected to each other via a battery interface 60 of the battery disconnect unit 18. The consumer 22 and the battery disconnect unit 18 are connected to each other via a consumer interface 62 of the battery disconnect unit 18.

1. A cooling plate (10) for cooling at least one component (12) and at least one power electronics unit (14), and for cooling at least one relay (16) of a battery disconnect unit (18) used for disconnecting a battery unit (20) from at least one consumer (22) of a drive system (24), the cooling plate comprising:
a first plate (26), and
a second plate (28),
wherein the first plate (26) and the second plate (28) comprise a component portion (30), wherein the at least one component (12) can be arranged on the component portion (30) of the first plate (26), and wherein a first flow chamber (32) for a coolant is provided in the component portion (30) between the first plate (26) and the second plate (28),
wherein the first plate (26) and the second plate (28) comprise a relay portion (34), wherein the at least one relay (16) of the battery disconnect unit (18) or at least one fastening element (36) of the at least one relay (16) of the battery disconnect unit (18) can be arranged on the relay portion (34), and wherein a second flow chamber (38) for a coolant is provided in the relay portion (34) between the first plate (26) and the second plate (28), wherein the first flow chamber (32) and the second flow chamber (38) are fluidically connected.

2. The cooling plate (10) according to claim 1, wherein the second flow chamber (38) of the relay portion (34) is channel-shaped.

3. The cooling plate (10) according to claim 1, wherein the first flow chamber (32) comprises a coolant distribution region (40) having a coolant inlet (42) and a deflection region (44) for deflecting the coolant into the second flow chamber (38), and wherein the second flow chamber (38) comprises a coolant collection region (46) having a coolant outlet (48).

4. The cooling plate (10) according to claim 1, wherein the first plate (26) and the second plate (28) in the relay portion (34) have a recess (50) for receiving the at least one relay (16) in certain regions and at least one support region (52) for supporting the at least one relay (16) or the at least one fastening element (36) of the at least one relay (16).

5. The cooling plate (10) according to claim 4, wherein at least sections of the second flow chamber (38) are designed to encircle the recess (50).

6. The cooling plate (10) according to claim 3, wherein a flow grid (54) is arranged between the coolant distribution region (40) and the deflection region (44) of the first flow chamber.

7. The cooling plate (10) according to claim 1, wherein the first plate (26) and/or the second plate (28) comprises a deformation for forming the first flow chamber (32) and the second flow chamber (38).

8. The cooling plate (10) according to claim 1, wherein a second thickness (D2) of the second plate (28) is at least 1.0 times a first thickness (D1) of the first plate (26).

9. A battery disconnect unit (18) for disconnecting a battery unit (20) from at least one consumer (22), the batter disconnect unit comprising:
a cooling plate (10) according to claim 1,
at least one ceramic substrate (56),
at least one component (12) of the at least one power electronics unit (14), wherein the at least one ceramic substrate (56) is arranged on an outer side (58) of the first plate (26) at the component portion (30), and wherein the at least one component (12) is arranged on the ceramic substrate (56), and wherein the first flow chamber (32) is arranged below the at least one component (12) of the at least one power electronics unit (14), and
at least one relay (16), wherein the at least one relay (16) is arranged at the relay portion (34), wherein the second flow chamber (38) is arranged below the at least one relay (16) or the at least one fastening element (36) of the at least one relay (16).

10. The battery disconnect unit (18) according to claim 9, wherein the at least one relay (16) is arranged in a recess (50) and is supported on at least one support region (52) via the at least one fastening element (36).

11. The battery disconnect unit (18) according to claim 9, wherein the at least one fastening element (36) is a busbar.

12. A drive system (24) comprising a battery unit (20), a consumer (22), and a battery disconnect unit (18) according to claim 9, wherein the battery unit (20) and the battery disconnect unit (18) are electronically connected to each other via a battery interface (60) of the battery disconnect unit (18), and wherein the consumer (22) and the battery disconnect unit (18) are connected to each other via a consumer interface (62) of the battery disconnect unit (18).

13. The cooling plate (10) according to claim 8, wherein a second thickness (D2) of the second plate (28) is at least 1.5 times a first thickness (D1) of the first plate (26).

14. The cooling plate (10) according to claim 8, wherein a second thickness (D2) of the second plate (28) is at least 2.0 times a first thickness (D1) of the first plate (26).
